(19) United States
(12) Patent Application Publication
(10) Pub. No.: US 2025/0096735 A1
(43) Pub. Date: Mar. 20, 2025

(54) Balanced Multipath Single-ended Amplifier Circuitry

(71) Applicant: Apple Inc., Cupertino, CA (US)

(72) Inventors: Yahia Z Ibrahim, Albany, CA (US); Preeti S Mulage, Saratoga, CA (US); David M Signoff, Santa Clara, CA (US)

(21) Appl. No.: 18/663,467

(22) Filed: May 14, 2024

Related U.S. Application Data
(60) Provisional application No. 63/584,116, filed on Sep. 20, 2023.

(51) Int. Cl. H03F 1/02; H03F 3/24

(52) U.S. Cl. CPC H03F 1/0288; H03F 3/245; H03F 2200/451

(57) ABSTRACT

Amplifier circuitry is provided that includes a splitter circuit, a combiner circuit, a first amplifier path coupled between the splitter circuit and the combiner circuit, and a second amplifier path coupled between the splitter circuit and the combiner circuit. The first amplifier path can include a first amplifier of a first type and a second amplifier of a second type different than the first type. The second amplifier path can include a third amplifier of the first type and a fourth amplifier of the second type. The first, second, third, and fourth amplifiers can be single-ended amplifiers with shunt inductors coupled at their outputs. The shunt inductors associated with the first and second amplifiers can be partially overlapped to save area. The shunt inductors associated with the third and fourth amplifiers can be partially overlapped to save area.

This application claims the benefit of U.S. Provisional Patent Application No. 63/584,116, filed Sep. 20, 2023, which is hereby incorporated by reference herein in its entirety.

### FIELD

This disclosure relates generally to electronic devices and, more particularly, to electronic devices with wireless communications circuitry.

### BACKGROUND

Electronic devices are often provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by and received at an antenna can be fed through one or more radio-frequency amplifiers. It can be challenging to design radio-frequency amplifiers for an electronic device. For instance, it can be difficult to maintain high output power efficiency and performance across different types of wireless signal modulation schemes.

### SUMMARY

An electronic device may include wireless communications circuitry. The wireless communications circuitry may include one or more processors or signal processing blocks for generating and receiving baseband (digital) signals, a transceiver having a transmitter for generating corresponding radio-frequency signals based on the baseband signals and having a receiver for generating corresponding baseband signals based on received radio-frequency signals, one or more radio-frequency transmitting amplifiers configured to amplify the radio-frequency signals for transmission by one or more antennas in the electronic device, and one or more radio-frequency receiving amplifiers configured to amplify radio-frequency signals received by one or more antennas in the electronic device.

An aspect of the disclosure provides amplifier circuitry that includes a splitter circuit, a combiner circuit, a first amplifier path coupled between the splitter circuit and the combiner circuit, the first amplifier path having a first amplifier of a first type and a second amplifier of a second type different than the first type, and a second amplifier path coupled between the splitter circuit and the combiner circuit, the second amplifier path having a third amplifier of the first type and a fourth amplifier of the second type. The first amplifier path can further include: a first input coupler having an input port coupled to the splitter circuit, a first output port coupled to the first amplifier, and a second output port coupled to the second amplifier; a first output coupler having a first input port coupled to the first amplifier, a second input port coupled to the second amplifier, and an output port coupled to the combiner circuit; a second input coupler having an input port coupled to the splitter circuit, a first output port coupled to the third amplifier, and a second output port coupled to the fourth amplifier; and a second output coupler having a first input port coupled to the third amplifier, a second input port coupled to the fourth amplifier, and an output port coupled to the combiner circuit.

The first amplifier can be a first single-ended amplifier, and the second amplifier can include a second single-ended amplifier. The amplifier circuitry can further include: a first inductor having a first terminal coupled to an output of the first single-ended amplifier and having a second terminal coupled to a positive power supply line; and a second inductor having a first terminal coupled to an output of the second single-ended amplifier and having a second terminal coupled to the positive power supply line. The first inductor has a first footprint, whereas the second inductor has a second footprint that is partially overlapping with the first footprint.

An aspect of the disclosure provides amplifier circuitry that includes a first input coupler, a first output coupler, a first single-ended amplifier coupled between the first input coupler and the first output coupler, a second single-ended amplifier coupled between the first input coupler and the first output coupler, a first inductor coupled to an output of the first single-ended amplifier, and a second inductor coupled to an output of the second single-ended amplifier. The amplifier circuitry can further include a second input coupler, a second output coupler, a third single-ended amplifier coupled between the second input coupler and the second output coupler, a fourth single-ended amplifier coupled between the second input coupler and the second output coupler, a third inductor coupled to an output of the third single-ended amplifier, and a fourth inductor coupled to an output of the fourth single-ended amplifier. The amplifier circuitry can further include: a splitter circuit having a first output port coupled to the first input coupler and having a second output port coupled to the second input coupler; and a combiner circuit having a first input port coupled to the first output coupler and having a second input port coupled to the second output coupler.

An aspect of the disclosure provides circuitry that includes a splitter having a first transformer and a first plurality of capacitors, a combiner having a second transformer and a second plurality of capacitors, a first input coupler coupled to a first output port of the splitter, a second input coupler coupled to a second output port of the splitter, a first impedance matching and inverting output coupler coupled to a first input port of the combiner, a second impedance matching and inverting output coupler coupled to a second input port of the combiner, a first single-ended amplifier coupled between the first input coupler and the first impedance matching and inverting output coupler, a second single-ended amplifier coupled between the first input coupler and the first impedance matching and inverting output coupler, a third single-ended amplifier coupled between the second input coupler and the second impedance matching and inverting output coupler, and a fourth single-ended amplifier coupled between the second input coupler and the second impedance matching and inverting output coupler.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having amplifiers in accordance with some embodiments.

FIG. 3 is a diagram of illustrative balanced amplifier circuitry having four parallel single-ended amplifiers in accordance with some embodiments.

FIG. 4 is a circuit diagram of the balanced amplifier circuitry of the type shown in FIG. 3 in accordance with some embodiments.

FIG. 5 is a diagram showing an illustrative pair of single-ended amplifiers having outputs coupled to partially overlapping shunt inductors in accordance with some embodiments.

### DETAILED DESCRIPTION

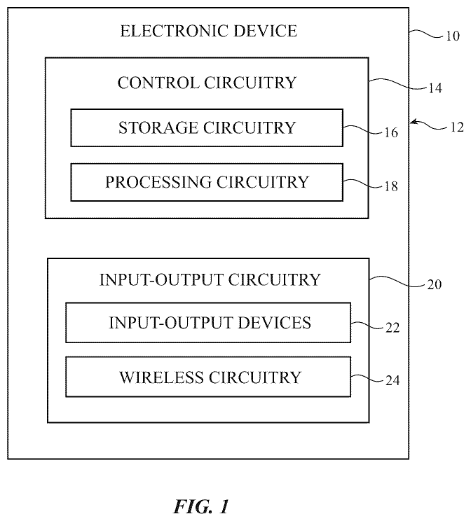

An electronic device such as device 10 of FIG. 1 may be provided with wireless circuitry. The wireless circuitry may include one or more amplifiers configured to amplify radio-frequency signals along a transmit path or a receive path. In accordance with some embodiments, radio-frequency amplifier circuitry may be implemented as two parallel Doherty amplifiers coupled together in a balanced fashion. The two parallel Doherty amplifiers can have inputs coupled to a balanced splitter and outputs coupled to a balanced combiner. Each Doherty amplifier can include two single-ended amplifiers having inputs coupled to a first single-transformer-based coupler configured to provide signal splitting and a 90 degree phase difference, and having outputs that are coupled to respective shunt inductors that are at least partially overlapping for zero coupling and that are coupled to a second single-transformer-based coupler configured to provide impedance inversion and impedance matching. Balanced Doherty amplifier circuitry having at least four amplifier paths configured in this way can be technically advantageous and beneficial by providing high efficiency and high voltage standing wave ratio (VSWR) resilience for different digital signal modulation schemes.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), 6G bands between 100-1000 GHz (e.g., sub-THz or THz bands), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

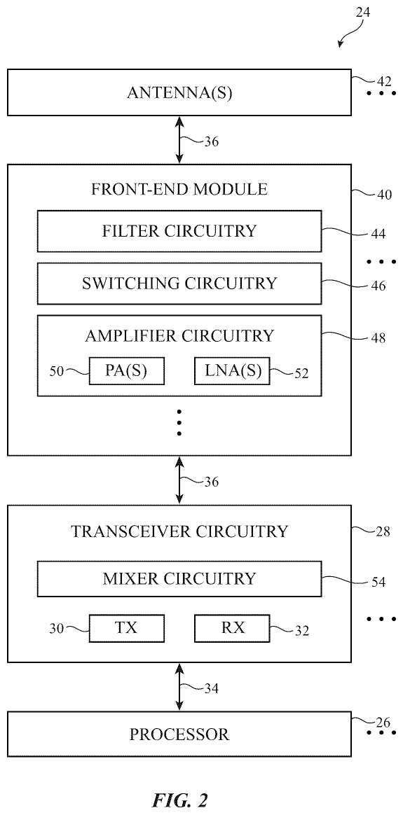

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26 into corresponding radio-frequency signals. For example, transceiver circuitry 28 may include mixer circuitry 54 for up-converting (or modulating) the transmit (baseband) signals to radio frequencies prior to transmission over antenna 42. The example of FIG. 2 in which processor 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry 54 for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

It can be challenging to design a radio-frequency amplifier. Radio-frequency amplifiers can be operated using different digital modulation schemes to transmit digital data over radio-frequency channels such as quadrature phase shift keying (QPSK) and quadrature amplitude modulation (QAM). QPSK is a type of phase modulation where four different phase states are used to represent different combinations of a two-bit symbol. The four phase states are separated by 90 degrees (e.g., 0°, 90°, 180°, 270°). On the other hand, QAM is a modulation scheme that combines both amplitude and phase modulation to encode digital data. Relative to QPSK, QAM allows for a higher number of symbols to be transmitted in each modulation interval, which can enable a higher data transmission rate. The number of symbols in QAM can be represented as “N-QAM,” where N is equal to the number of possible symbols. For example, 16-QAM has 16 constellation points (e.g., 4 amplitude levels and 4 phase states), 64-QAM has 64 constellation points, 256-QAM has 256 constellation points, and so on.

It can be difficult to design a radio-frequency amplifier that can achieve both high efficiency for QPSK signals while maintaining good performance (i.e., good error vector magnitude) for 64/256-QAM signals. For instance, a conventional power amplifier that might be able to offer high efficiency for QPSK signals typically exhibits larger variation across voltage standing wave ratio (VSWR) angles, which degrades the performance for 64/256-QAM signals. It is within this context that the present embodiments arise. Although the examples herein sometimes refer to QPSK and QAM, the embodiments described herein can optionally be extended to other types of wireless modulation schemes, including but not limited to binary phase shift keying (BPSK), minimum shift keying (MSK), orthogonal frequency division multiplexing (OFDM), continuous phase modulation (CPM), and/or other digital signal modulation schemes.

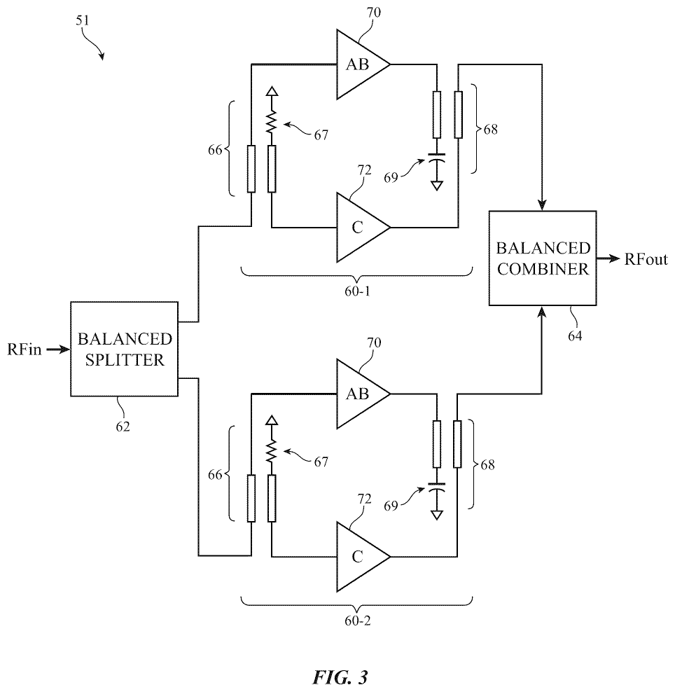

In accordance with an embodiment FIG. 3 is a diagram of illustrative balanced amplifier circuitry 51 that can achieve high efficiency for QPSK signals or other modulation schemes while also maintaining satisfactory performance (e.g., satisfactory EVM) for 64/256-QAM signals or other modulation schemes. Amplifier circuitry 51 can represent a radio-frequency transmitting amplifier (e.g., power amplifier 50 of FIG. 2) or might represent a radio-frequency receiving amplifier (e.g., low noise amplifier 52 of FIG. 2). As shown in FIG. 3, amplifier circuitry 51 may include a balanced splitter circuit such as balanced splitter 62, a balanced combiner circuit such as balanced combiner 64, a first amplifier path 60-1 coupled between balanced splitter 62 and balanced combiner 64, and a second amplifier path 60-2 coupled between balanced splitter 62 and balanced combiner 64. The example of FIG. 3 having two parallel amplifier paths 60-1 and 60-2 interposed between splitter 62 and combiner 64 is illustrative. If desired, four, six, eight, or other even number of amplifier paths 60 can optionally be coupled between splitter 62 and combiner 64 in a balanced fashion.

Balanced splitter 62 may have an input port RFin configured to receive a radio-frequency signal, a first output port coupled to the first amplifier path 60-1, and a second output port coupled to the second amplifier path 60-2. Balanced splitter 62 can therefore sometimes be referred to as an input coupler. For example, balanced splitter 62 may be a 900 input coupler or other types of input coupler. Balanced combiner 64 may have a first input port coupled to the first amplifier path 60-1, a second input port coupled to the second amplifier path 60-2, and an output port RFout on which a combined radio-frequency output signal can be generated. Balanced combiner 64 can sometimes be referred to as an output coupler. For example, balanced combiner 64 may be a 90° output coupler or other types of output coupler.

The first amplifier path 60-1 may include a first amplifier 70, a second amplifier 72, an input coupler 66 coupled to the inputs of amplifiers 70 and 72, and an output coupler 68 coupled to the outputs of amplifiers 70 and 72. Input coupler 66 may have an input port coupled to balanced splitter 62, an isolation port coupled to resistor 67 (or other resistive or passive component), a first output port coupled to amplifier 70, and a second output port coupled to amplifier 72. For example, input coupler 66 may be a 90° input coupler or other types of input coupler. Output coupler 68 may have a first input port coupled to amplifier 70, a second input port coupled to amplifier 72, an isolation port coupled to capacitor 69 (or other capacitive, inductive, open, or short passive component), and an output port coupled to balanced combiner 64. For example, output coupler 68 may be a 900 output coupler or other types of output coupler.

Amplifier 70 may be a first type of amplifier such as a class A or class AB amplifier, whereas amplifier 72 may be a second type of amplifier, different than the first type of amplifier, such as a class C amplifier. Different types of classes of amplifiers can have different biasing schemes, operating efficiency, linearity performance, and applications. For example, a class AB amplifier may be biased such that its output transistors are slightly turned on even when there's little input signal to minimize the crossover distortion, whereas a class C amplifier may be biased to consume relatively less power for higher efficiency. As another example, the linearity of class AB amplifiers is relatively high due to its biasing that reduces crossover distortion, whereas the linearity of class C amplifiers is relatively poor due to its biasing that can introduce higher levels of distortion. Amplifiers 70 and 72 of two different types coupled together in this way using input and output couplers 66 and 68 are sometimes referred to collectively as a Doherty amplifier. The example above where amplifier 70 is a class A/AB amplifier and where amplifier 72 is a class C amplifier is illustrative. In general, amplifiers 70 and 72 within amplifier path 60-1 can each represent an amplifier of any type, including but not limited to a class A amplifier, a class AB amplifier, a class D amplifier, a class E amplifier, a class F amplifier, a class G amplifier, a class H amplifier, a class I amplifier, a class T amplifier, or other types of amplifiers.

Similarly, the second amplifier path 60-2 may include a first amplifier 70, a second amplifier 72, an input coupler 66 coupled to the inputs of amplifiers 70 and 72, and an output coupler 68 coupled to the outputs of its own amplifiers 70 and 72. Input coupler 66 may have an input port coupled to balanced splitter 62, an isolation port coupled to resistor 67 (or other resistive or passive component), a first output port coupled to amplifier 70, and a second output port coupled to amplifier 72. For example, input coupler 66 may be a 900 input coupler or other types of input coupler. Output coupler 68 may have a first input port coupled to amplifier 70, a second input port coupled to amplifier 72, an isolation port coupled to capacitor 69 (or other capacitive or passive component), and an output port coupled to balanced combiner 64. For example, output coupler 68 may be a 90° output coupler or other types of output coupler.

Amplifier 70 of amplifier path 60-2 may be a first type of amplifier such as a class A or class AB amplifier, whereas amplifier 72 of amplifier path 60-2 may be a second type of amplifier, different than the first type of amplifier, such as a class C amplifier. Amplifiers 70 and 72 of two different types coupled together in this way within amplifier path 60-2 using input and output couplers 66 and 68 are sometimes referred to collectively as a Doherty amplifier. The described here where amplifier 70 is a class A/AB amplifier and where amplifier 72 is a class C amplifier is illustrative. In general, amplifiers 70 and 72 within amplifier path 60-2 can each represent an amplifier of any type, including but not limited to a class A amplifier, a class AB amplifier, a class D amplifier, a class E amplifier, a class F amplifier, a class G amplifier, a class H amplifier, a class I amplifier, a class T amplifier, or other types of amplifiers.

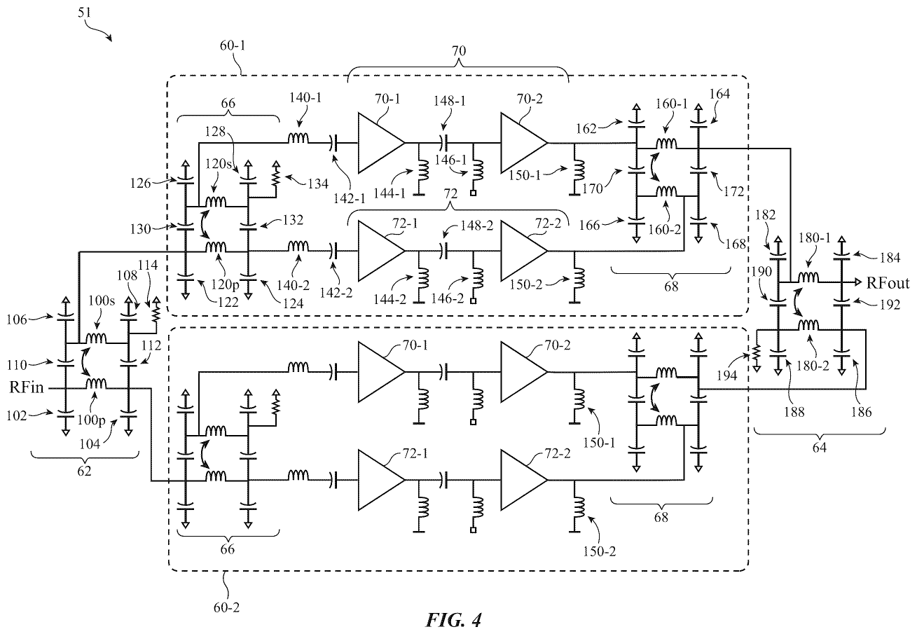

FIG. 4 is a circuit diagram showing an illustrative implementation of balanced amplifier circuitry 51 of the type described in connection with FIG. 3. As shown in FIG. 4, balanced splitter 62 may have an input port RFin, a first output port coupled to the first amplifier path 60-1, a second output port coupled to the second amplifier path 60-2, and internal components such as capacitors 102, 104, 106, 108, 110, and 112, resistor 114, and a transformer having primary coil (winding) 100p and secondary coil (winding) 100s. Primary coil 100p may have a first terminal coupled to the input port RFin and a second terminal coupled to the second output port of splitter 62. Secondary coil 100s may have a first terminal coupled to the first output port of splitter 62 and a second terminal coupled to an isolation port of splitter 62. Shunt resistor 114 may be coupled to the isolation port (e.g., to the second terminal of secondary coil 100s).

Capacitor 102 may be shunted at input port RFin (e.g., capacitor 102 has a first terminal coupled to the first terminal of primary coil 100p and a second terminal coupled to a ground power supply line). The ground power supply line is sometimes referred to as a ground line or ground. Capacitor 104 may be shunted at the second output port of splitter 62 (e.g., capacitor 104 has a first terminal coupled to the second terminal of primary coil 100p and a second terminal coupled to ground). Capacitor 106 may be shunted at the first output port of splitter 62 (e.g., capacitor 106 has a first terminal coupled to the first terminal of secondary coil 100s and a second terminal coupled to the ground line). Capacitor 108 may be shunted at the isolation port of splitter 62 (e.g., capacitor 108 has a first terminal coupled to the second terminal of secondary coil 100s and a second terminal coupled to the ground line). Capacitor 110 may have a first terminal coupled to the first terminal of primary coil 100p and a second terminal coupled to the first terminal of secondary coil 100s. Capacitor 112 may have a first terminal coupled to the second terminal of primary coil 100 and a second terminal coupled to the second terminal of secondary coil 100s. Balanced splitter 62 configured in this way is sometimes referred to as a transformer-based balanced splitter.

Balanced combiner 64 may have a first input port coupled to the first amplifier path 60-1, a second input port coupled to the second amplifier path 60-2, an output port RFout, and internal components such as capacitors 182, 184, 186, 188, 190, and 192, resistor 194, and a transformer having first coil (winding) 180-1 and second coil (winding) 180-2. First coil 180-1 may have a first terminal coupled to the first input port of combiner 64 and a second terminal coupled to RFout. Second coil 180-2 may have a first terminal coupled to an isolation port of combiner 64 and a second terminal coupled to the second input port of combiner 64. Shunt resistor 194 may be coupled to the isolation port (e.g., to the first terminal of second coil 180-2).

Capacitor 182 may be shunted at the first input port of combiner 64 (e.g., capacitor 182 has a first terminal coupled to the first terminal of first coil 180-1 and a second terminal coupled to the ground line). Capacitor 184 may be shunted at the RFout port (e.g., capacitor 184 has a first terminal coupled to the second terminal of coil 180-1 and a second terminal coupled to ground). Capacitor 186 may be shunted at the second input port of combiner 64 (e.g., capacitor 186 has a first terminal coupled to the second terminal of coil 180-2 and a second terminal coupled to ground). Capacitor 188 may be shunted at the isolation port of combiner 64 (e.g., capacitor 188 has a first terminal coupled to the first terminal of coil 180-2 and a second terminal coupled to the ground line). Capacitor 190 may have a first terminal coupled to the first terminal of coil 180-1 and a second terminal coupled to the first terminal of coil 180-2. Capacitor 192 may have a first terminal coupled to the second terminal of coil 180-1 and a second terminal coupled to the second terminal of coil 180-2. Balanced combiner 64 configured in this way is sometimes referred to as a transformer-based balanced combiner.

Turning now to the first amplifier path 60-1, the first amplifier (e.g., amplifier 70 in FIG. 3) may be implemented as a single-ended amplifier that includes a first single-ended driver stage 70-1 coupled in series with a single-ended output stage 70-2. Interstage matching components such as a series inductor 148-1 and shunt inductors 144-1 and 146-1 may be coupled between driver stage 70-1 and output stage 70-2. These interstage matching components are sometimes referred to collectively as an interstage matching circuit. Similarly, the second amplifier (e.g., amplifier 72 in FIG. 3) may be implemented as a single-ended amplifier that includes a second single-ended driver stage 72-1 coupled in series with a single-ended output stage 72-2. Interstage matching components such as a series inductor 148-2 and shunt inductors 144-2 and 146-2 may be coupled between driver stage 72-1 and output stage 72-2. These interstage matching components are sometimes referred to collectively as an interstage matching circuit.

Input coupler 66 of the first amplifier path 60-1 may include a transformer having primary coil (winding) 120p and a secondary coil (winding) 120s, capacitors 122, 124, 126, 128, 130, and 132, and resistor 134. Primary coil 120p may have a first terminal coupled to the balanced splitter 62 and a second terminal coupled to second driver stage 72-1 via series inductor 140-2 and series capacitor 142-2. Secondary coil 120s may have a first terminal coupled to the first driver stage 70-1 via series inductor 140-1 and series capacitor 142-1 and a second terminal. Shunt resistor 134 may have a first terminal coupled to the second terminal of coil 120s and a second terminal shorted to ground. Capacitor 122 may have a first terminal coupled to the first terminal of coil 120p and a second terminal shorted to ground. Capacitor 124 may have a first terminal coupled to the second terminal of coil 120p and a second terminal shorted to ground. Capacitor 126 may have a first terminal coupled to the first terminal of coil 120s and a second terminal shorted to ground. Capacitor 128 may have a first terminal coupled to the second terminal of coil 120s and a second terminal shorted to ground. Capacitor 130 may be coupled between the first terminal of coil 120p and the first terminal of coil 120s. Capacitor 132 may be coupled between the second terminal of coil 120p and the second terminal of coil 120s. Input coupler 66 configured in this way is sometimes referred to as a transformer-based input coupler.

Output coupler 68 of the first amplifier path 60-1 may include a transformer having a first coil (winding) 160-1 and a second coil (winding) 160-2, and capacitors 162, 164, 166, 168, 170, and 172. First coil 160-1 may have a first terminal coupled to the first output stage 70-2 and a second terminal coupled to balanced combiner 64. Second coil 160-2 may have a first terminal and a second terminal coupled to second output stage 72-2. Capacitor 162 may have a first terminal coupled to the first terminal of coil 160-1 and a second terminal shorted to ground. Capacitor 164 may have a first terminal coupled to the second terminal of coil 160-2 and a second terminal shorted to ground. Capacitor 166 may have a first terminal coupled to the first terminal of coil 160-2 and a second terminal shorted to ground. Capacitor 168 may have a first terminal coupled to the second terminal of coil 160-2 and a second terminal shorted to ground. Capacitor 170 may be coupled between the first terminal of coil 160-1 and the first terminal of coil 160-2. Capacitor 172 may be coupled between the second terminal of coil 160-1 and the second terminal of coil 160-2. Output coupler 68 configured in this way is sometimes referred to as a transformer-based output coupler.

The structure of the second amplifier path 60-2 is generally identical to that already described in connection with the first amplifier path 60-1 and need not be reiterated in detail to avoid obscuring the present embodiment. The difference with the second amplifier path 60-2 is that the input coupler 66 of second amplifier path 60-2 is coupled to the second terminal of coil 100p within balanced splitter 62 and that the output coupler 68 of second amplifier path 60-2 is coupled to the second terminal of coil 180-2 within balanced splitter 64.

As shown in FIG. 4, balanced amplifier circuitry 51 includes four parallel amplifier paths (e.g., two parallel amplifiers in the first amplifier path 60-1 and two parallel amplifiers in the second amplifier path 60-2). To alleviate area concerns with having this many parallel amplifiers, all of the amplifier stages (e.g., driver stages 70-1 and 72-1 and output stages 70-2 and 72-2) can be implemented as single-ended amplifier stages, which are dramatically smaller in size compared to differential amplifier stages. Input coupler 66 can be configured to provide signal splitting to amplifiers 70-1 and 70-2 with a 90 degree phase shift between the split signals. Coupler 66 is therefore sometimes referred to as a 90 degree input coupler. The transformer-based output couplers 68 are configured to provide both impedance matching and impedance inversion functions (obviating the need to have separate circuits for both), which further minimizes area at the output side. The output couplers 68 of the first and second amplifier paths 60-1 and 60-2 are therefore sometimes referred to as impedance matching and inverting output couplers.

Differential amplifiers typically require baluns for output impedance matching. Baluns can consume a large amount of area and can also exhibit limited bandwidth. In accordance with some embodiments, amplifiers 70 and 72 can have outputs coupled to shunt inductors such as inductors 150-1 and 150-2, respectively. As shown in FIG. 4, the first single-ended output stage 70-2 can have an output coupled to shunt inductor 150-1 (e.g., inductor 150-1 has a first terminal coupled to the output of amplifier 70 and a second terminal shorted to a positive power supply line on which a positive power supply voltage Vdd can be provided), whereas the second single-ended output stage 72-2 can have an output coupled to shunt inductor 150-2 (e.g., inductor 150-2 has a first terminal coupled to the output of amplifier 72 and a second terminal shorted to the positive power supply line). The use of shunt inductors 150-1 and 150-2 at the output of the single-ended amplifiers can be technically advantageous and beneficial by providing improved bandwidth over baluns while offering area savings (i.e., shunt inductors are smaller than transformer-based baluns).

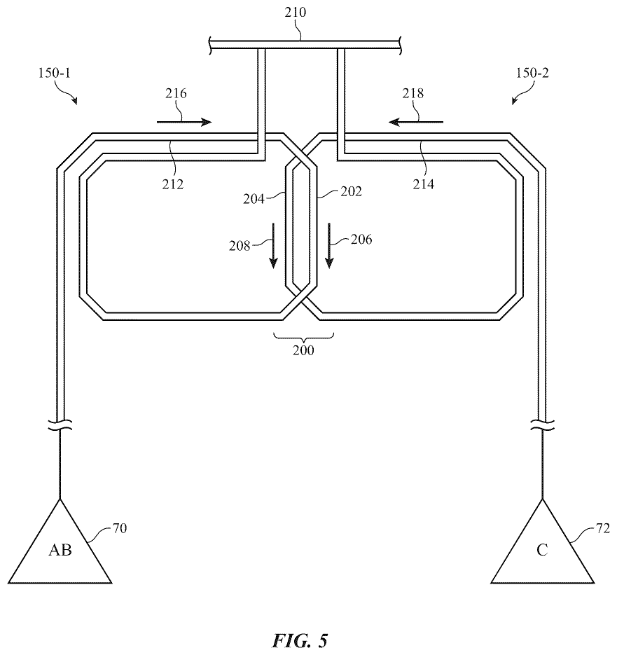

To further minimize area, shunt inductors 150-1 and 150-2 can be at least partially overlapping (see, e.g., FIG. 5). FIG. 5 is a diagram showing shunt inductor 150-1 that is partially overlapping with inductor 150-2. As shown in FIG. 5, inductor 150-1 that is coupled to the output of first amplifier 70 can include a first set of coil windings coupled to Vdd positive power supply line 210, whereas inductor 150-2 that is coupled to the output of second amplifier 72 can include a second set of coil windings coupled to positive power supply line 210. The first set of coil windings of inductor 150-1 can be formed in one or more metal routing layers in an interconnect (dielectric) stack. The second set of coil windings of inductor 150-2 can be formed in one or more metal routing layers in the interconnect (dielectric) stack. In general, the two output shunt inductors 150-1 and 150-2 of the two separate amplifiers 70 and 72 should not exhibit any magnetic or inductive coupling between the two inductors. The conventional way to minimize magnetic coupling would be to place the shunt inductors as far away from each other as possible; doing so would, however, increase the overall area and cost of amplifier 51.

In accordance with some embodiments, shunt inductors 150-1 and 150-2 can be overlapped such that a winding segment 202 of inductor 150-1 is disposed adjacent to a winding segment 204 of shunt inductor 150-2. In other words, inductor 150-1 may have a first footprint, and inductor 150-2 may have a second footprint that partially overlaps with the first footprint (e.g., a right portion of the first footprint overlaps with a left portion of the second footprint as shown in the plan view of FIG. 5). In the example of FIG. 5, the currents flowing through the non-overlapping coil or winding segments 212 and 214 are in opposite directions (as indicated by arrows 216 and 218), which introduce an amount of negative coupling between inductors 150-1 and 150-2. On the other hand, the currents flowing through coil or winding segments 202 and 204 in the overlapping region 200 are in the same direction (as indicated by arrows 206 and 208), which introduce an amount of positive coupling between inductors 150-1 and 150-2. Overlapping inductor footprints is acceptable here because the direction of current flow 206 through winding segment 202 is identical to the direction of current flow 208 through winding segment 204. Configured in this way with identical current flow directions in the overlapping region 200, the amount of coupling between shunt inductors 150-1 and 150-2 can be minimized or reduced to zero.

The example of FIG. 5 in which shunt inductors 150-1 and 150-2 each have windings with at least one turn forming a rectangular shape is merely illustrative. If desired, shunt inductors 150-1 and 150-2 can each have windings with any number of turns forming footprints of any suitable shape. Shunt inductors 150-1 and 150-2 can have the same shape or can optionally have different shapes. If desired, shunt inductors 150-1 and 150-2 can be overlapped in other ways to further minimize the overall area of amplifier circuitry 51.

The methods and operations described above in connection with FIGS. 1-5 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. Amplifier circuitry comprising:
a splitter circuit;
a combiner circuit;
a first amplifier path coupled between the splitter circuit and the combiner circuit, the first amplifier path having a first amplifier of a first type and a second amplifier of a second type different than the first type; and
a second amplifier path coupled between the splitter circuit and the combiner circuit, the second amplifier path having a third amplifier of the first type and a fourth amplifier of the second type.

2. The amplifier circuitry of claim 1, wherein the first amplifier path further comprises:
a first input coupler having an input port coupled to the splitter circuit, a first output port coupled to the first amplifier, and a second output port coupled to the second amplifier; and
a first output coupler having a first input port coupled to the first amplifier, a second input port coupled to the second amplifier, and an output port coupled to the combiner circuit.

3. The amplifier circuitry of claim 2, wherein the second amplifier path further comprises:
a second input coupler having an input port coupled to the splitter circuit, a first output port coupled to the third amplifier, and a second output port coupled to the fourth amplifier; and
a second output coupler having a first input port coupled to the third amplifier, a second input port coupled to the fourth amplifier, and an output port coupled to the combiner circuit.

4. The amplifier circuitry of claim 2, wherein the first amplifier path further comprises:
a resistor having a first terminal coupled to an isolation port of the first input coupler and having a second terminal coupled to a power supply line; and
a capacitor having a first terminal coupled to an isolation port of the first output coupler and having a second terminal coupled to the power supply line.

5. The amplifier circuitry of claim 2, wherein the first input coupler comprises:
a transformer having a primary coil and a secondary coil, wherein
the primary coil has a first terminal coupled to the splitter circuit and has a second terminal coupled to the second amplifier, and
the secondary coil has a first terminal coupled to the first amplifier and a second terminal coupled to an isolation port of the first input coupler.

6. The amplifier circuitry of claim 5, wherein the first input coupler further comprises:
a first capacitor having a first terminal coupled to the first terminal of the primary coil and having a second terminal coupled to a power supply line;
a second capacitor having a first terminal coupled to the second terminal of the primary coil and having a second terminal coupled to the power supply line;
a third capacitor having a first terminal coupled to the first terminal of the secondary coil and having a second terminal coupled to the power supply line; and
a fourth capacitor having a first terminal coupled to the second terminal of the secondary coil and having a second terminal coupled to the power supply line.

7. The amplifier circuitry of claim 6, wherein the first input coupler further comprises:
a fifth capacitor coupled between the first terminal of the primary coil and the first terminal of the secondary coil; and
a sixth capacitor coupled between the second terminal of the primary coil and the second terminal of the secondary coil.

8. The amplifier circuitry of claim 2, wherein the first output coupler comprises:
a transformer having a first coil and a second coil, wherein
the first coil has a first terminal coupled to the first amplifier and has a second terminal coupled to the combiner circuit, and
the second coil has a first terminal and has a second terminal coupled to the second amplifier.

9. The amplifier circuitry of claim 8, wherein the first output coupler further comprises:
a first capacitor having a first terminal coupled to the first terminal of the first coil and having a second terminal coupled to a power supply line;
a second capacitor having a first terminal coupled to the second terminal of the first coil and having a second terminal coupled to the power supply line;
a third capacitor having a first terminal coupled to the first terminal of the second coil and having a second terminal coupled to the power supply line; and
a fourth capacitor having a first terminal coupled to the second terminal of the second coil and having a second terminal coupled to the power supply line.

10. The amplifier circuitry of claim 9, wherein the first output coupler further comprises:
a fifth capacitor coupled between the first terminal of the first coil and the first terminal of the second coil; and
a sixth capacitor coupled between the second terminal of the first coil and the second terminal of the second coil.

11. The amplifier circuitry of claim 2, wherein
the first amplifier comprises a first driver stage coupled to a first output stage via a first interstage matching circuit, and
the second amplifier comprises a second driver stage coupled to a second output stage via a second interstage matching circuit.

12. The amplifier circuitry of claim 2, wherein the first amplifier comprises a first single-ended amplifier and wherein the second amplifier comprises a second single-ended amplifier, further comprising:
a first inductor having a first terminal coupled to an output of the first single-ended amplifier and having a second terminal coupled to a positive power supply line; and
a second inductor having a first terminal coupled to an output of the second single-ended amplifier and having a second terminal coupled to the positive power supply line.

13. The amplifier circuitry of claim 12, wherein the first inductor has a first footprint and wherein the second inductor has a second footprint that is partially overlapping with the first footprint.

14. The amplifier circuitry of claim 13, wherein the first inductor has a first winding with a first winding segment, wherein the second inductor has a second winding with a second winding segment disposed adjacent to the first winding segment within an overlapping region of the first and second footprints, and wherein a direction of current flow through the first winding segment is identical to a direction of current flow through the second winding segment.

15. The amplifier circuitry of claim 1, wherein
the splitter circuit comprises a first transformer and a first plurality of capacitors, and
the combiner circuit comprises a second transformer and a second plurality of capacitors.

16. Amplifier circuitry comprising:
a first input coupler;
a first output coupler;
a first single-ended amplifier coupled between the first input coupler and the first output coupler;
a second single-ended amplifier coupled between the first input coupler and the first output coupler;
a first inductor coupled to an output of the first single-ended amplifier; and
a second inductor coupled to an output of the second single-ended amplifier.

17. The amplifier circuitry of claim 16, further comprising:
a second input coupler;
a second output coupler;
a third single-ended amplifier coupled between the second input coupler and the second output coupler;
a fourth single-ended amplifier coupled between the second input coupler and the second output coupler;
a third inductor coupled to an output of the third single-ended amplifier; and
a fourth inductor coupled to an output of the fourth single-ended amplifier.

18. The amplifier circuitry of claim 17, further comprising:
a splitter circuit having a first output port coupled to the first input coupler and having a second output port coupled to the second input coupler; and
a combiner circuit having a first input port coupled to the first output coupler and having a second input port coupled to the second output coupler.

19. The amplifier circuitry of claim 16, wherein
the first inductor has a first footprint of a given shape and is coupled to a positive power supply line,
the second inductor has a second footprint of the given shape and is coupled to the positive power supply line, and
the second footprint partially overlaps with the first footprint.

20. Circuitry comprising:
a splitter having a first transformer and a first plurality of capacitors;
a combiner having a second transformer and a second plurality of capacitors;
a first input coupler coupled to a first output port of the splitter;
a second input coupler coupled to a second output port of the splitter;
a first impedance matching and inverting output coupler coupled to a first input port of the combiner;
a second impedance matching and inverting output coupler coupled to a second input port of the combiner;
a first single-ended amplifier coupled between the first input coupler and the first impedance matching and inverting output coupler;
a second single-ended amplifier coupled between the first input coupler and the first impedance matching and inverting output coupler;
a third single-ended amplifier coupled between the second input coupler and the second impedance matching and inverting output coupler; and
a fourth single-ended amplifier coupled between the second input coupler and the second impedance matching and inverting output coupler.
